(19) United States
(12) Patent Application Publication
(10) Pub. No.: US 2025/0365866 A1
(43) Pub. Date: Nov. 27, 2025

(54) CIRCUIT BOARD AND METHOD OF CIRCUIT PLATING THEREOF

(71) Applicant: Unimicron Technology Corp., Taoyuan City (TW)

(72) Inventors: Young Sheng BAI, Taoyuan City (TW); Ying Shih CHEN, Taoyuan City (TW)

(21) Appl. No.: 19/218,677

(22) Filed: May 27, 2025

Related U.S. Application Data
(60) Provisional application No. 63/652,164, filed on May 27, 2024.

(51) Int. Cl. H05K 1/11; H05K 3/40

(52) U.S. Cl. CPC H05K 1/115; H05K 3/4076

(57) ABSTRACT

A circuit board and a method of circuit plating thereof are provided. The circuit board includes a substrate, a conductive pillar and a first circuit layer. The substrate includes a first surface, a second surface opposite the first surface, and a hole extending from the first surface toward the second surface. The first circuit layer is disposed on the first surface and is connected to the conductive pillar. The conductive pillar includes N cylindrical metal shells disposed inside the hole and arranged in a concentric pattern, in which a (K-1) cylindrical metal shell surrounds and covers the Kth cylindrical metal shell, and an interface is formed between the (K-1) and the Kth cylindrical metal shells, and the 1st cylindrical metal shell covers and contacts a sidewall of the hole, in which N and K are both positive integers and N≥K≥3.

### CROSS-REFERENCE TO RELATED APPLICATION

This application claims priority to U.S. Provisional Application Ser. No. 63/652,164, filed May 27, 2024, which is herein incorporated by reference in its entirety.

### BACKGROUND

### Field of Disclosure

The present disclosure provides a circuit board and a method for plating a circuit thereof.

### Description of Related Art

In current electronic equipment, with the enhancement of functionality and working efficiency, the heat generated by increasing during the electronic equipment in operation, resulting in an increase in the temperature of the electronic equipment, thereby adversely affecting the performance and reliability of the electronic equipment. Therefore, the circuit board in the electronic equipment must have a certain degree of heat resistance to ensure that the circuit board can still operate normally when the temperature of the electronic equipment is high.

### SUMMARY

The present disclosure according to at least one embodiment provides a circuit board and a method of circuit plating thereof to facilitate enhancing the heat resistance of a circuit board in an electronic device.

At least one embodiment of the present disclosure provides a circuit board including a substrate, a conductive pillar, and a first circuit layer. The substrate includes a first surface, a second surface opposite the first surface, and a hole extending from the first surface toward the second surface. The conductive pillar includes N cylindrical metal shells disposed inside the hole and arranged in a concentric pattern, in which a (K-1)th cylindrical metal shell surrounds and covers the Kth cylindrical metal shell, and an interface is formed between the (K-1)th cylindrical metal shell and the Kth cylindrical metal shell, and a 1st cylindrical metal shell covers and contacts a sidewall of the hole, in which N and K are both positive integers and N≥K≥3.

At least one embodiment of the present disclosure, a thickness of the aforementioned 1st cylindrical metal shell is less than each of the thicknesses of the other cylindrical metal shells.

At least one embodiment of the present disclosure, each of the thicknesses of the aforementioned 2nd cylindrical metal shell to an Nth cylindrical metal shell is from 0.31 μm to 5 mm.

At least one embodiment of the present disclosure, the aforementioned first circuit layer includes a plurality of first layers in a stack, in which the thickness of each of the first layers in a stack is 0.31 μm to 5 μm.

At least one embodiment of the present disclosure, there is a thickness error of 10% to 13% is in each of the aforementioned 2nd cylindrical metal shell to the Nth cylindrical metal shell.

At least one embodiment of the present disclosure, the aforementioned circuit board further includes a second circuit layer disposed on the second surface, in which the second circuit layer includes a plurality of second layers in a stack, in which the thickness of each of the second layers in a stack is from 0.31 μm to 5 μm.

At least one embodiment of the present disclosure, the aforementioned circuit board further includes a filler fills a plated through-hole of the conductive pillar.

At least one embodiment of the present disclosure provides a method of circuit plating, includes providing a substrate. A hole is formed in the substrate. N cylindrical metal shells are sequentially formed in the hole to form a conductive pillar within the hole, in which the step of sequentially forming the N cylindrical metal shells includes: forming a 1st cylindrical metal shell that covers and contacts a sidewall of the hole; applying a pulsed current to the first cylindrical metal shell to plating (N-1) cylindrical metal shells on the 1st cylindrical metal shell, in which the N cylindrical metal shells are arranged in a concentric pattern, and a minimum value of the pulsed current is greater than zero. Thereafter, a first circuit layer is formed on the first surface of the substrate, in which the first circuit layer is connected to the conductive pillar.

At least one embodiment of the present disclosure, the duty cycle of the pulsed current referred to in the aforementioned method of circuit plating is from 87% to 97%.

At least one embodiment of the present disclosure, the current density of the pulsed current referred to in the aforementioned circuit plating method is from 0.01 ASD to 3 ASD.

At least one embodiment of the present disclosure, the 1st cylindrical metal shell referred to in the aforementioned circuit plating method is formed by electroless plating.

At least one embodiment of the present disclosure, the hole referred to in the aforementioned circuit plating method is a blind hole, and the depth of the blind hole is less than the thickness of the substrate.

A least one embodiment of the present disclosure, the hole referred to in the aforementioned circuit plating method is a though hole, the depth of the through hole is equal to the thickness of the substrate, and conductive pillar is formed in the through hole.

At least one embodiment of the present disclosure, the aforementioned method of circuit plating further includes: after the conductive pillar is formed within the through hole, a filler fills in a plated through-hole of the conductive pillar, in which an Nth cylindrical metal shell defines the plated through-hole.

Based on the aforementioned. In the aforementioned embodiments of the present disclosure of the circuit board and its circuit plating method, applying a pulsed current can form the aforementioned plurality of cylindrical metal shells arranged in concentric pattern, and help to control the thickness and number of the cylindrical metal shells during the process, in which these cylindrical metal shells can help to reduce the variation in stress due to the thermal expansion in order to ensure to keep the structural stability of the conductive pillar under a high-temperature environment. In this way, the circuit boards are able to operate normally when the temperature of the electronic devices is high, further contributing to the performance and reliability of the electronic devices.

### BRIEF DESCRIPTION OF THE DRAWINGS

The disclosure can be more fully understood by reading the following detailed description of the embodiment, with reference made to the accompanying drawings as follows:

FIG. 1A is a cross-sectional schematic drawing of a circuit board illustrating at least one embodiment of the present disclosure.

FIG. 1B is a schematic drawing of the profile drawn from the circuit board profile line A-A profile of FIG. 1A.

FIGS. 2A to 2D are cross-sectional schematic drawings of at least one embodiment of the circuit plating method of the present disclosure.

FIG. 3 is a cross-sectional schematic drawing of a circuit board illustrating another embodiment of the present disclosure.

FIG. 4 is a graph plotting a current versus time curve of the pulsed current of at least one embodiment of the present disclosure.

FIG. 5 is a box-and-whisker plot drawing resistance value shifts for at least one embodiment of the present disclosure of a circuit board subjected to different solder reflow cycles.

### DETAILED DESCRIPTION

In the following text, in order to clearly present the technical features of this case, the dimensions (such as length, width, thickness and depth) of the components (such as layers, electrodes, base boards, regions, etc.) in the drawings are expressed in unequal proportions to be enlarged, and the number of some components will be reduced. Therefore, the description and explanation of the embodiments below are not limited to the number of components and the sizes and shapes of the components in the drawings, but should cover the size, shape, and deviations in both caused by actual manufacturing processes and/or tolerances. For example, regions shown or described as flat may typically have rough and/or non-linear characteristics. Additionally, the acute angles shown can be rounded. Therefore, the components shown in the drawings of this case are mainly for illustration, and are not intended to accurately depict the actual shapes of the components, nor are they intended to limit the patent scope of this case.

It should be understood that although the disclosure can use the terms herein that a first, a second, a third etc. to describe various elements, components, regions, layers or sections. But these elements, components, regions, layers or sections are not limited in the disclosure. In addition, these terms are only used to distinguish one element, component, region, layer or section from another element, component, region, layer or section. Thus, a first element, component, region, layer or section discussed below could be termed a second element, component, region, layer or section without departing form the conceptual teachings of the present disclosure.

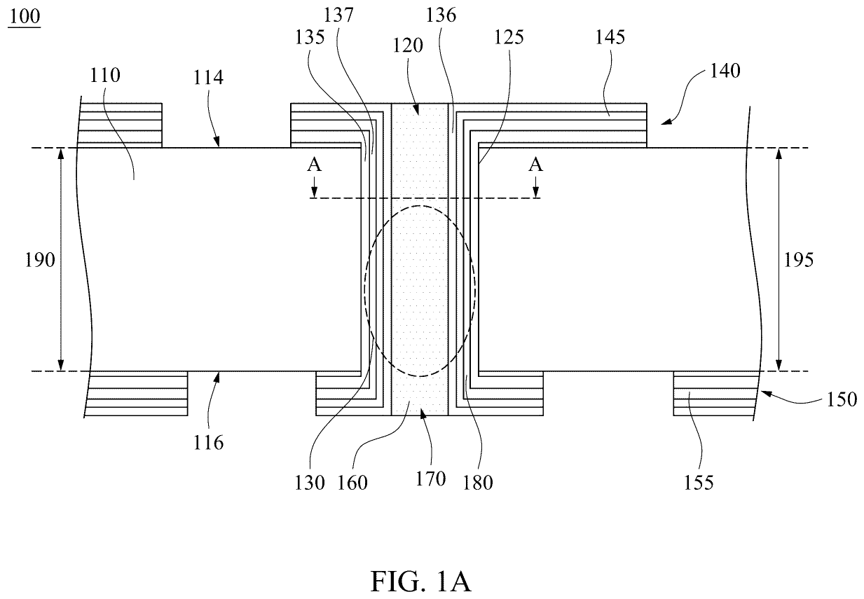

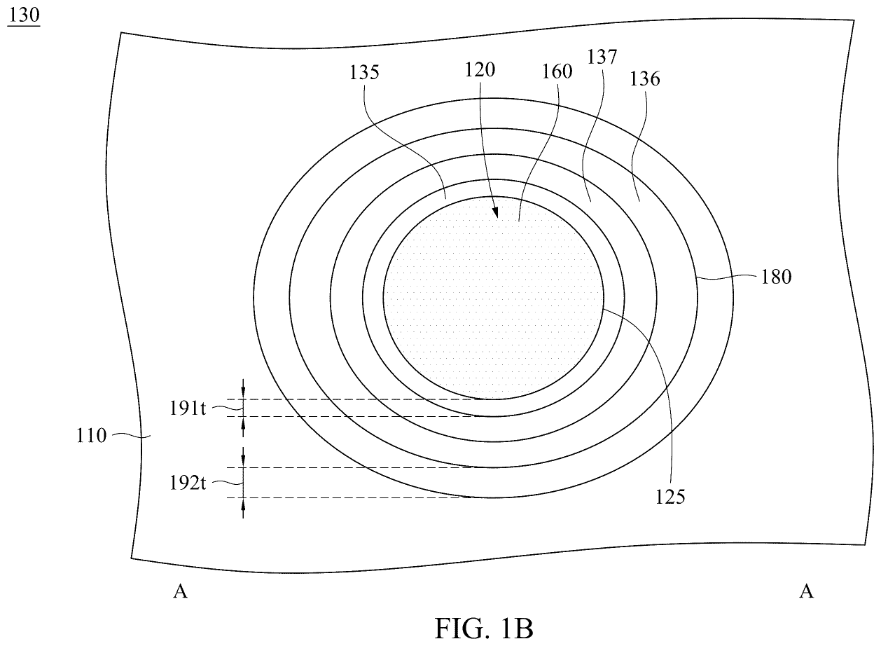

FIG. 1A is a cross-sectional schematic drawing of a circuit board 100 illustrating at least one embodiment of the present disclosure. FIG. 1B is a schematic drawing of the profile drawn from the circuit board 100 profile line A-A profile of FIG. 1A. Referring to FIG. 1A and FIG. 1B, circuit board 100 includes a substrate 110, a conductive pillar 130 and a first circuit layer 140. The substrate has a first surface 114, a second surface 116 opposite the first surface 114, and a hole 120 extending from the first surface 114 toward the second surface 116. The first circuit layer 140 is disposed on the first surface 114 and is connected to the conductive pillar 130.

The circuit board 100 may include a plurality of conductive pillars 130, in other words, the number of holes 120 may be more than one. Thus, the number of conductive pillars 130, i.e., the number of holes 120, is not limited by FIG. 1A. In addition, the substrate 110 has a different state, which may be a composite substrate having an insulating layer and a circuit layer (or a metal layer, such as a metal core layer, metal core). Alternatively, the substrate 110 may be an insulated substrate that includes a dielectric material.

The dielectric material of the substrate 110 includes at least one of Polyimide (PI), Polyethylene (PE), Benzocyclobutene (BCB), Acrylonitrile Butadiene Styrene (ABS), Epoxy, Bistmaleimide Triazine (BT), Ajinomoto Built-up Film (ABF), Aramide, Liquid Crystal Polymer (LCP), Poly-tetra-fluoroethylene (PTFE), Photosensitive Polyimide (PSPI), and glass fiber.

The conductive pillar 130 includes N cylindrical metal shells 136 disposed inside the hole 120 and arranged in a concentric pattern (as shown in FIG. 1B), where N is a positive integer and represents the number of cylindrical metal shells 136 (cylindrical). In the embodiment of FIG. 1A, the conductive pillar 130 includes 4 cylindrical metal shells 136 (i.e., N=4), in which a 1st cylindrical metal shell 135 covers and contacts the sidewall 125 of the hole 120 and surrounds and covers a 2nd cylindrical metal shell 135, and an interface 180 is formed between the 1st cylindrical metal shell 135 and the 2nd cylindrical metal shell 135. Additionally, each of the cylindrical metal shells 135, 137, and 136 may have a cylindrical or angular shape.

By analogy, the 2nd cylindrical metal shell 135 surrounds and covers the 3rd cylindrical metal shell 135, and an interface 180 is formed between the 2nd cylindrical metal shell 135 and the 3rd cylindrical metal shell 135. The 3rd cylindrical metal shell 135 surrounds and covers the 4th cylindrical metal shell 135, and an interface 180 is formed between the 3rd cylindrical metal shell 135 and the 4th cylindrical metal shell 135.

Accordingly, the (K-1)th cylindrical metal shell 136 surrounds and covers the Kth cylindrical metal shell 136, and an interface 180 is formed between the (K-1)th cylindrical metal shell 136 and the Kth cylindrical metal shell 136, in which K is a positive integer and N≥K≥3. In addition, the interface 180 can be sliced, e.g. by Failure Analysis (FA) slicing technique, and observed with an industrial optical microscope or a tool microscope (e.g. optical microscope model STM6 or STM7 from Olympus).

From FIG. 1B, the thickness 191t (0.31 microns to 5 microns) of the 1st cylindrical metal shell 135 is less than each of the thicknesses 192t of these other cylindrical metal shells 136 (e.g., the 2nd through 4th cylindrical metal shells 136). Each of the thicknesses 192t of the cylindrical metal shells 136 which is other than the 1st cylindrical metal shell 135, i.e., each of the thicknesses of the 2nd cylindrical metal shell 137 through the 4th cylindrical metal shell 136 (i.e., N=4), is from 0.31 μm to 5 μm.

From FIG. 1A, the first circuit layer 140 has a plurality of first layers in a stack 145, in which the thickness (not labeled) of each of the first layers in a stack 145 is 0.31 μm to 5 μm. There is a thickness error of 10% to 13% in each of the 2nd cylindrical metal shell 137 to the Nth cylindrical metal shell 136 is, so that the thicknesses 192t of the cylindrical metal shells 137 and 136 (shown in FIG. 1B) are substantially the same or similar. The substrate 110 also includes a second circuit layer 150, which is disposed on the second surface 116, in which the second circuit layer 150 includes a plurality of second layers in a stack 155, in which the thickness (no labeled) of each of the second layers in a stack 155 is from 0.31 μm to 5 μm. The substrate 110 also includes a filler 160, which fills a plated through-hole 170 of the conductive pillar 130.

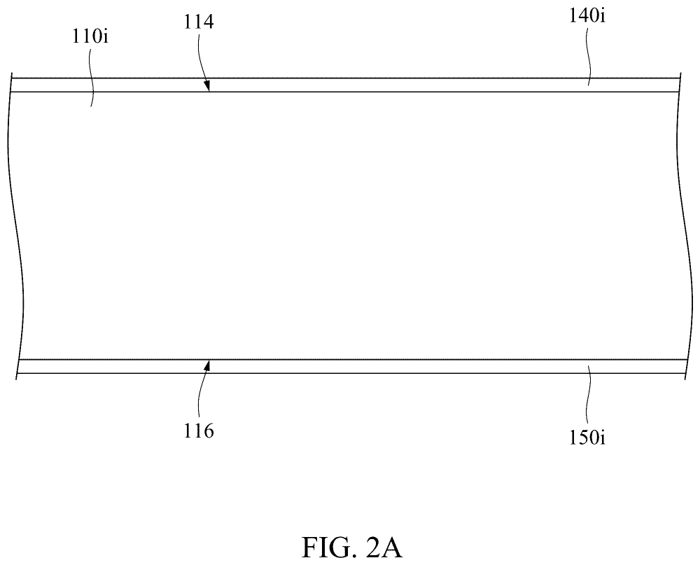

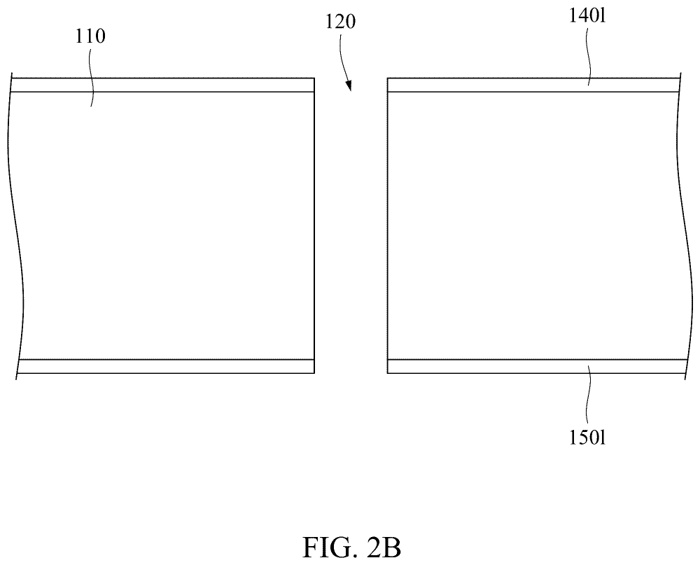

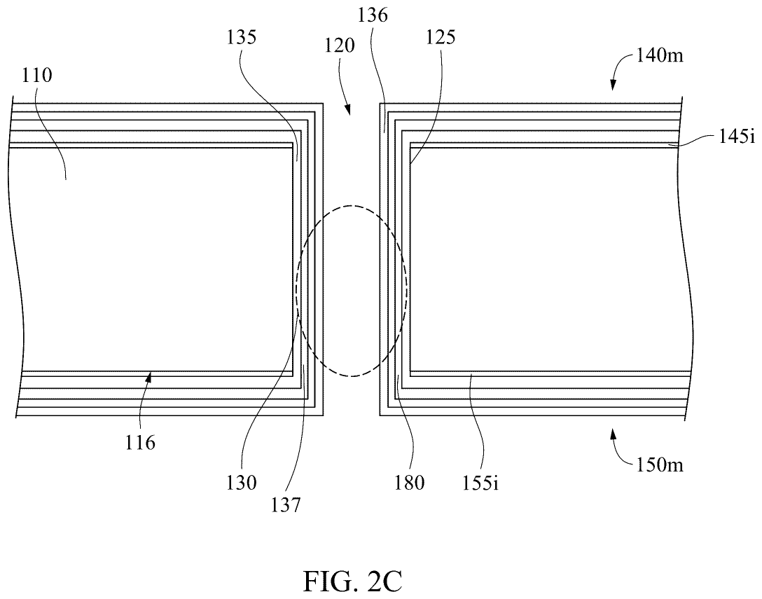

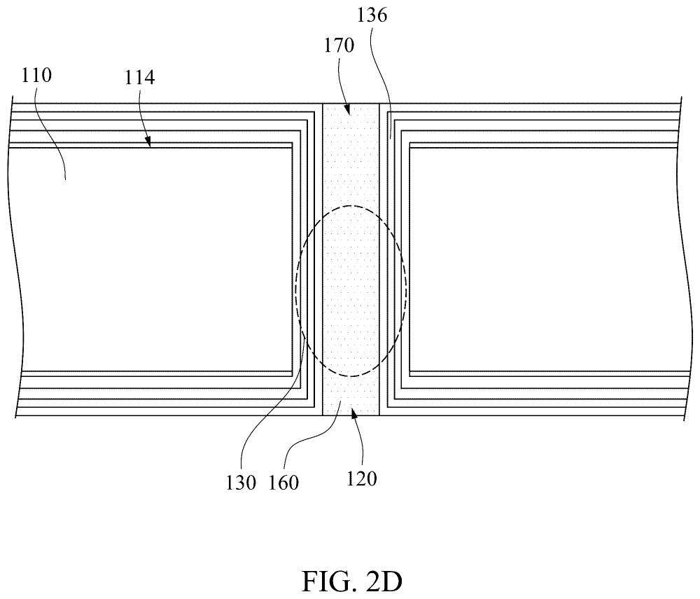

FIGS. 2A to 2D are cross-sectional schematic drawings of at least one embodiment of the circuit plating method of the present disclosure. Referring to FIG. 2A, first, a substrate 110i is provided, in which the substrate 110i is an initial substrate and is different from the aforementioned substrate 110. For example, the substrate 110i has no holes 120. In the embodiment of FIG. 2A, a first metal layer 140i (i.e., the predecessor of the first circuit layer) covers the first surface 114 of the substrate 110i. A second metal layer 150i (i.e., the predecessor of the second circuit layer) covers the second surface 116 of the substrate 110i. (The first metal layer 140i is formed into the first circuit layer after a subsequent process).

In this embodiment, the first metal layer 140i and the second metal layer 150i can be copper foil, and the first metal layer 140i, the second metal layer 150i and the substrate 110i can be provided by a copper foil substrate, i.e., the first metal layer 140i, the second metal layer 150i and the substrate 110i can form a copper foil substrate. Additionally, in other embodiments, the first metal layer 140i and the second metal layer 150i may be formed using Physical Vapor Deposition (hereinafter referred to as PVD), in which the PVD may be Evaporative PVD or Sputtering PVD.

Referring to FIG. 2B, a hole 120 is formed in the substrate 110i to form the substrate 110. In the embodiment of FIG. 2B, the hole is through hole, and the depth 195 of the through hole is equal to the thickness 190 of the substrate 110 (as show in FIG. 1A). The through hole can be formed by at least one of mechanical drilling and Laser Ablation Pattern Opening (LAPO).

The thicknesses (not labeled) of both the first metal layer 140i and the second metal layer 150i in FIG. 2A may be thinned to form the thinner initial first stacked layer 145i and the initial second stacked layer 155i in FIG. 2C, in which a grinding method may be used to thin the thicknesses (not labeled) of both the first metal layer 140i (or 140l) and the second metal layer 150i (or 150l).

Referring to FIG. 2C, thereafter, N cylindrical metal shells 136 are sequentially formed in the hole 120 to form a conductive pillar 130 within the hole 120, in which the hole 120 is a through hole. The steps for sequentially forming the N cylindrical metal shells 136 include: forming a 1st cylindrical metal shell 135 that covers and contacts the sidewall 125 of the hole 120. The 1st cylindrical metal shell 135 is formed by electroless plating (i.e., chemical plating) and can be used as a seed layer, in which the cylindrical metal shell 135 can be copper, gold, aluminum-copper alloy, and nickel.

After forming a 1st cylindrical metal shell 135, plating is performed and a pulse current is applied to the 1st cylindrical metal shell 135 to sequentially plate (N-1) cylindrical metal shells 136 and 137 on the 1st cylindrical metal shell 135, in which the N cylindrical metal shells 136 are arranged in a concentric pattern (as illustrated in FIG. 1B), and a minimum value of the pulse current is greater than zero. During the process of electroplating, a deposit metal may be formed on the first surface 114 of the substrate 110 to form a first metal layer 140m, in which the first metal layer 140m is connected to the conductive pillar 130. Furthermore, a second metal layer 150m may also be simultaneously formed on the second surface 116 of the substrate 110, in which the second metal layer 150m is connected to the conductive pillar 130.

Referring to FIG. 2D, in the embodiment of FIG. 2D, the hole 120 is though hole. After the conductive pillar 130 has just been formed within the through hole, the conductive pillar 130 may be a hollow metal pillar with a plated through-hole 170, in which the Nth cylindrical metal shell 136 defines the plated through-hole 170. After, a filler 160 fills in the plated through-hole 170 of the conductive pillar 130. In other undrawn embodiments, the plated through-hole 170 of the conductive pillar 130 may also be fully filled, i.e., the plated through-hole 170 may be filled with metal (e.g., copper) to the extent that the conductive pillar 130 may not have plated through-hole 170 for the filler 160 to fill. In other words, the plated through-hole 170 may be filled with a solid metal pillar.

Next, referring to FIGS. 2D and 1A, in the embodiment of FIGS. 2D and 1A, a first circuit layer 140 is formed on a first surface 114 of the substrate 110, in which the first circuit layer 140 is connected to the conductive pillar 130. There is also a second circuit layer 150 formed on a second surface 116 of the substrate 110, in which the second circuit layer 150 is connected to the conductive pillar 130. At this point, one type of circuit board 100 has been substantially fabricated, as shown in FIG. 1A. In addition, in other embodiments, FIG. 2D may later be subjected to grinding to thin the first circuit layer 140 and the second circuit layer 150.

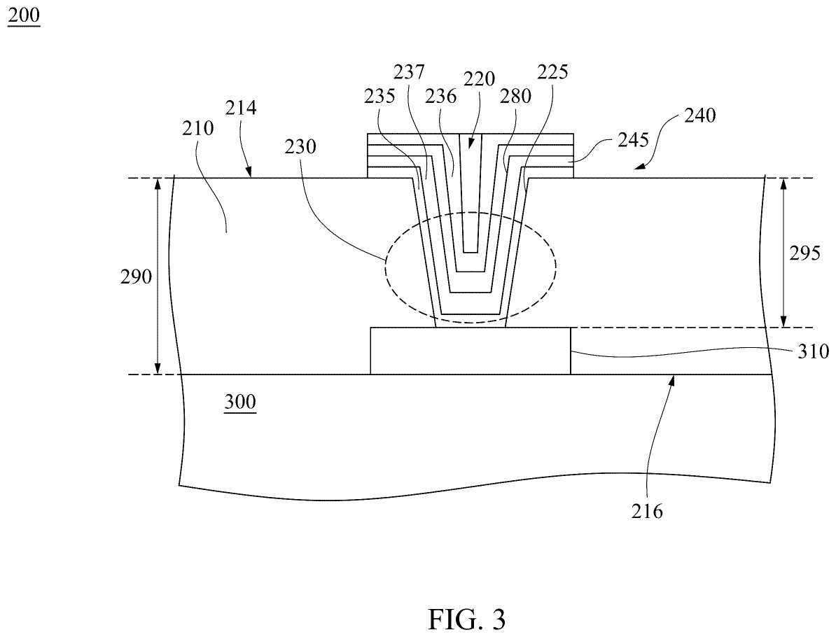

FIG. 3 is a cross-sectional schematic drawing of a circuit board 200 illustrating another embodiment of the present disclosure. The structure of the circuit board 200 of FIG. 3 is similar to the structure of the circuit board 100 of FIG. 1A, whereas the two differ in that the holes are different and the circuit board 200 includes at least one pad 310 and a circuit body 300. Referring to FIG. 3, the circuit board 200 also includes a substrate 210, a conductive pillar 230, a first circuit layer 240, a pad 310, and a circuit body 300. The substrate 210 is an insulating layer and has a first surface 214, a second surface 216 opposite the first surface 214, and a hole 220 extending from the first surface 214 toward the second surface 216, in which the hole 220 is a blind hole and the depth 295 of the hole 220 is less than the thickness 290 of the substrate 210. The substrate 210 is disposed on the circuit body 300, in which the circuit body 300 has at least one circuit layer, e.g. the pad 310 shown in FIG. 3.

The first circuit layer 240 is disposed on the first surface 214 and is connected to the conductive pillar 230. The conductive pillar 230 includes N cylindrical metal shells 236, which may be individually shaped as truncated cones or polygonal cones, disposed inside the hole 220 and arranged in concentric pattern (similar to FIG. 1B), in which the (K-1)th cylindrical metal shell 136 surrounds and covers the Kth cylindrical metal shell 236, and an interface 280 is formed between the (K-1)th cylindrical metal shell 236 and the Kth cylindrical metal shell 236.

The 1st cylindrical metal shell 235 covers and contacts the sidewall 225 of the hole 220, in which N and K are positive integers and N≥K≥3. The thickness of the 1st cylindrical metal shell 235 (not labeled) is less than each of the thicknesses (not labeled) of the other cylindrical metal shells 236. Each of the thicknesses of the 2nd cylindrical metal shell 237 to the Nth cylindrical metal shell 236 is from 0.31 μm to 5 μm. The first circuit layer 240 has a plurality of first layers in a stack 245, in which the thickness (not labeled) of each of the first layers in a stack 245 is 0.31 μm to 5 μm. There is the thickness error of 10% to 13% in each of the 2nd cylindrical metal shell 237 to the Nth cylindrical metal shell 236.

The circuit plating method of the circuit board 200 is similar to the circuit plating method of the circuit board 100, and the main difference between the two is in the different types of holes. In the embodiment of FIG. 3, a hole 220 is formed in the substrate 210, but the hole 220 does not extend into the circuit body 300. Next, electroless plating and electroplating are sequentially performed to sequentially form N cylindrical metal shells 236 in the holes 220, thereby forming conductive pillar 230 inside the holes 220, in which the plating fills the holes 220, i.e., the conductive pillar 230 is a solid metal pillar and fills the holes 220.

The steps for sequentially forming the N cylindrical metal shells 236 include: forming a 1st cylindrical metal shell 235 that covers and contacts the sidewall 225 of the hole 220. The 1st cylindrical metal shell 235 is formed by electroless plating, and in this embodiment, the 1st cylindrical metal shell 235 is formed by chemical copper plating and can serve as a seed layer.

Next, a pulsed current is applied to the 1st cylindrical metal shell 235 to plating (N-1) cylindrical metal shells 236 on the 1st cylindrical metal shell 235, in which the N cylindrical metal shells 236 are arranged in a concentric pattern, and the minimum value of the pulsed current is greater than zero. Next, a first circuit layer 240 is formed on the first surface 214 of the substrate 210, in which the first circuit layer 240 is connected to the conductive pillar 230.

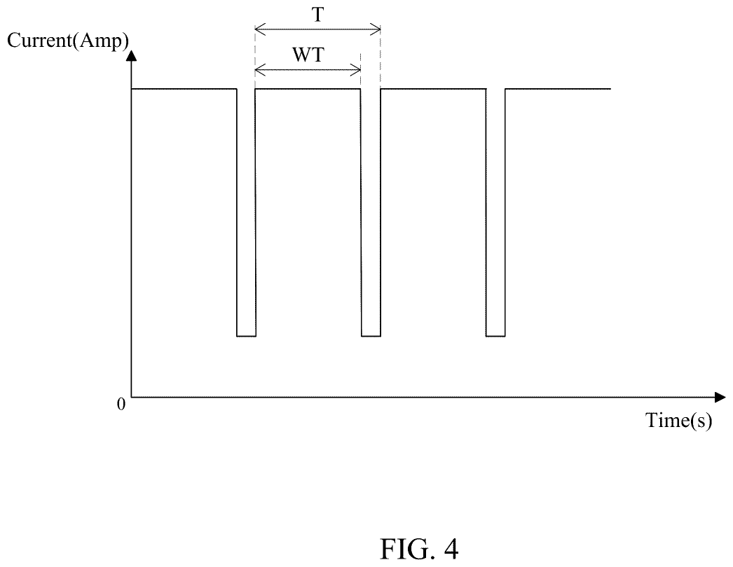

FIG. 4 is a graph plotting a current versus time curve of the pulsed current of at least one embodiment of the present disclosure. Referring to FIG. 4, pulsed current duty cycle (Duty Cycle) as disclosed herein refers to the proportion of pulse width time WT relative to pulse period T (one pulse time) in a pulse period T. The duty cycle equation is WT/T. The duty cycle of the pulsed current is from 87% to 97% for this disclosure. The current density of the pulsed current is from 0.01 ASD to 3 ASD, and the minimum value of the pulsed current is greater than zero.

The pulsed currents shown in FIG. 4 can be used to fabricate the circuit boards 100 and 200 described above, and to form the cylindrical metal shells 136 and 137, or 236 and 237. The 1st pulse signal of the pulsed current curve corresponds to the 2nd cylindrical metal shells 137 and 237, and the 2nd pulse signal of the pulsed current curve corresponds to the 3rd cylindrical metal shells 136 and 236. By analogy, the (N-1) th pulse signal of the pulsed current curve corresponds to the Nth cylindrical metal shell 136 and 236. Moreover, as can be seen in FIG. 4, the minimum value of the pulsed current is greater than zero, thereby contributing to the creation of interfaces 180 and interfaces 280 that are less likely to cause flaking with the cylindrical metal shells 135, 136, 137, 235, 236, 237 (as shown in FIGS. 1A and 3).

The embodiments of the disclose the above plating methods for the circuit boards 100 and 200, in which the foregoing embodiments are illustrated by way of example with the subtractive method, but the disclosure is also applicable to the additive method and the semi-additive method, without limitation. Besides, the present disclosure is not limited to through holes and blind holes, but even both can be present in a circuit board, i.e., the circuit board 100 can include conductive pillars 130 and 230.

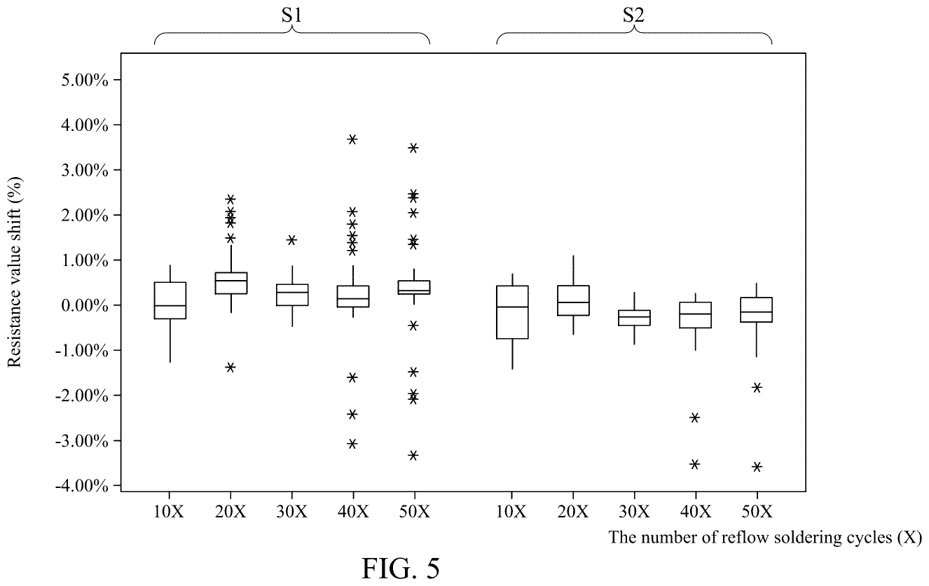

This embodiment of the disclosure was subjected to a Reliability Test or Reliability Assurance, hereinafter referred to as RA, which was performed under the conditions of baking at a temperature of 125° C. for a period of 24 hours. Next, reflow soldering is performed at an ambient temperature of 60° C. and an ambient humidity of 60%, with a reflow soldering temperature of 260° C. The number of reflow soldering cycles is 10 (represented by 10× in FIG. 5), 20 (20×), 30 (30×), 40 (40×), and 50 (50×), in which X is the number of cycles, and the results of the measured resistance value shifts are plotted in FIG. 5. FIG. 5 is a box-and-whisker plot of resistance value shifts for at least one embodiment of the circuit board of the present disclosure subjected to different number of reflow soldering cycles. Comparative embodiment S1 is a circuit board without a multi-layer cylindrical metal shell. Embodiment S2 is a circuit board with a multi-layer cylindrical metal shell.

Referring to FIG. 5, after multiple reflow soldering impacts of comparative embodiment S1 and the present embodiment S2, the circuit board of the present embodiment S2 is less prone to produce outliers with large resistance values compared to the comparative embodiment S1, meaning that the internal stresses between the metal shell, circuit layer and the substrate are less in the embodiment of the present disclosure. And the conductive pillar has good structural strength under the reflow soldering impacts in the present embodiment S2, so that the circuit board of the present embodiment S2 is less likely to cause cracking and spalling, and thus the resistance value of the present embodiment S2 is more stable.

Additionally, after a cycle of multiple reflow soldering impacts, the present embodiment S2 at reflow soldering cycles of 40× and 50× partially produces values of reduced resistance, as found by slicing, e.g., FA slicing. Some of the interfaces disappear between the metal shells or between the circuit layers, resulting in a partial fusion, so that in addition to a decrease in resistance, there is greater adhesion between the layers of the cylindrical metal shells, the first layers in a stack and the second layers in a stack, and it is less likely to flake off.

Consequently, in the circuit board and the method for plating the circuit of at least one embodiment of the present disclosure, the applied pulsed current helps to control the thickness and the number of cylindrical metal shells in the process, in which the cylindrical metal shells help to reduce the variation in stress due to the thermal expansion, and thus reduce the risk of cracks, flaking, and unstable resistance between the metal shells and the circuit layer due to thermal deformation, thereby ensuring to keep the structural stability of the conductive pillar under the high-temperature environment. In this way, the circuit boards are able to operate normally even when the temperature of the electronic devices is high, so as to facilitate improving the performance and reliability of the electronic devices.

Although the present application has been disclosed in various embodiments as above, it is not intended to limit the present application. The components of several embodiments are summarized above so that those with person having ordinary skill in the art (abbreviated PHOSITA) to which the present disclosure belongs can more easily understand the opinion of the embodiments. Those PHOSITA of the present disclosure should understand that they can design or modify other processes and structures based on the embodiments of the present disclosure to achieve the same purposes and/or advantages as the embodiments introduced here. Those PHOSITA to which the present disclosure belongs should also understand that such equivalent processes and structures do not deviate from the spirit and scope of the present disclosure, and they can be used, various changes, substitutions and substitutions are made, without departing from the spirit and scope of the present disclosure. So the protection scope of this application shall be determined by the appended patent application scope. Although the present disclosure has been described in considerable detail with reference to certain embodiments thereof, other embodiments are possible. Therefore, the spirit and scope of the appended claims should not be limited to the description of the embodiments contained herein.

What is claimed is:

1. A circuit board, comprising:
a substrate, having a first surface, a second surface opposite the first surface, and a hole extending from the first surface toward the second surface;
a conductive pillar, comprising:
N cylindrical metal shells, disposed inside the hole and arranged in a concentric pattern, wherein a (K-1)th cylindrical metal shell surrounds and covers a Kth cylindrical metal shell; and
an interface, formed between the (K-1)th cylindrical metal shell and the Kth cylindrical metal shell, and a 1st cylindrical metal shell covering and contacting a sidewall of the hole, wherein N and K are positive integers and N≥K≥3; and
a first circuit layer, disposed on the first surface and connected to the conductive pillar.

2. The circuit board of claim 1, wherein a thickness of the 1st cylindrical metal shell is less than each of the thicknesses of the other cylindrical metal shells.

3. The circuit board of claim 2, wherein each of the thicknesses of a 2nd cylindrical metal shell to an Nth cylindrical metal shell is from 0.31 μm to 5 μm.

4. The circuit board of claim 1, wherein the first circuit layer includes a plurality of first layers in a stack, wherein a thickness of each of the first layers in a stack is 0.31 μm to 5 μm.

5. The circuit board of claim 1, wherein there is a thickness error of 10% to 13% in each of a 2nd cylindrical metal shell to an Nth cylindrical metal shell.

6. The circuit board of claim 1, further comprising:
a second circuit layer, disposed on the second surface, wherein the second circuit layer includes a plurality of second layers in a stack, wherein a thickness of each of the second layers in a stack is from 0.31 μm to 5 μm.

7. The circuit board of claim 1, further comprising:
a filler, filling a plated through-hole of the conductive pillar.

8. A method of circuit plating, comprising:
providing a substrate;
forming a hole in the substrate;
sequentially forming N cylindrical metal shells in the hole to form a conductive pillar within the hole, wherein the step of sequentially forming the N cylindrical metal shells comprising:
forming a 1st cylindrical metal shell that covers and contacts a sidewall of the hole; and
applying a pulsed current to the 1st cylindrical metal shell to plating (N-1) cylindrical metal shells on the 1st cylindrical metal shell, wherein the N cylindrical metal shells are arranged in a concentric pattern, and a minimum value of the pulsed current is greater than zero; and
forming a first circuit layer on a first surface of the substrate, wherein the first circuit layer is connected to the conductive pillar.

9. The method of circuit plating of claim 8, wherein a duty cycle of the pulsed current is from 87% to 97%.

10. The method of circuit plating of claim 8, wherein a current density of the pulsed current is from 0.01 ASD to 3 ASD.

11. The method of circuit plating of claim 8, wherein the 1st cylindrical metal shell is formed by electroless plating.

12. The method of circuit plating of claim 8, wherein the hole is a blind hole, and a depth of the blind hole is less than a thickness of the substrate.

13. The method of circuit plating of claim 8, wherein the hole is a though hole, a depth of the through hole is equal to a thickness of the substrate, and the conductive pillar is formed in the through hole.

14. The method of circuit plating of claim 13, further comprising:
after the conductive pillar is formed within the through hole, a filler filling in a plated through-hole of the conductive pillar, wherein an Nth cylindrical metal shell defines the plated through-hole.
